(19) United States
(12) Patent Application Publication
(10) Pub. No.: US 2006/0172477 A1
(43) Pub. Date: Aug. 3, 2006

(54) MOS field effect transistor and manufacture method therefor

(75) Inventor: Masashi Shima, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/117,668

(22) Filed: Apr. 29, 2005

(30) Foreign Application Priority Data
Jan. 20, 2005 (JP) 2005-12509

(51) Int. Cl. H01L 29/739

(52) U.S. Cl. 438/197

(57) ABSTRACT

An MOS field effect transistor which improves the mobility of electrons and holes of an nMOS and a pMOS by applying larger tensile stress to a stressed Si channel in a lateral direction than that applied to a conventional structure without increasing a Ge composition of a buffer SiGe layer, and thus achieves a faster operation speed and lower power consumption, and a method of manufacturing the MOS field effect transistor. The method of manufacturing an MOS field effect transistor includes the steps of: forming a gate electrode on a top surface of a substrate comprising a compound layer having a lattice constant different from a lattice constant of silicon, and a silicon layer via an insulating film; forming a sidewall on a side wall of the gate electrode; exposing a side wall of the compound layer; and forming a silicon film on the side wall of the compound layer in a lattice matched manner.

### CROSS-REFERENCE TO RELATED APPLICATIONS

This application is based upon and claims the benefit of priority from the prior Japanese Patent Application No. 2005-12509, filed on Jan. 20,2005, the entire contents of which are incorporated herein by reference.

### BACKGROUND OF THE INVENTION

1. Field of the Invention

The present invention relates to an MOS (Metal Oxide Semiconductor) field effect transistor that has a heterojunction structure having the lamination of two types of semiconductor layers with different lattice constants, to one of which stress is applied, and a method of manufacturing the MOS field effect transistor.

2. Description of the Related Art

The performances of conventional MOS field effect transistors have been improved by miniaturization of the structures. For faster information processing and data communication and lower power consumption, there are demands for MOS field effect transistors with enhanced performances which ensures a faster operation with a low leak current. The miniaturization of MOS field effect transistors according to the conventional scaling rules is approaching the limit.

A technology of improving the mobility by introducing stress into a channel to change the physical property of the channel material is disclosed as one way of improving the operation speed.

In Japanese Patent Application Laid-Open No. H9-321307 and Japanese Patent Application Laid-Open No. 2001-332745, for example, electron mobility is improved significantly by laminating silicon (Si) on a buffer silicon germanium (SiGe) layer and applying great stress thereon, thereby improving the characteristic of an nMOS field effect transistor.

Japanese Patent Application Laid-Open No. H10-92947 discloses a fast and high performance integrated transistor achieved by preparing, on the same Si substrate, a pMOSFET formed at a part of a compression-stressed first SiGe layer, and an nMOSFET formed at a tensile-stressed Si layer on a second SiGe layer.

To significantly increase a drive current by improving the mobility of electrons or holes, however, a Ge composition of the buffer SiGe layer must be set to, for example, 30% or more. This inevitably increases the dislocation density, thereby increasing the leak current, which increases the power consumption of the device. While reducing the Ge composition decreases the dislocation density, thus reducing the leak current, the amount of stress of the Si channel layer becomes smaller, which undesirably reduces the improvement on the mobility.

### SUMMARY OF THE INVENTION

In view of the above problems, it is an object of the present invention to provide an MOS field effect transistor, which significantly improves the mobility of electrons and holes of an nMOS and a pMOS by applying larger tensile stress to a stressed Si channel in a lateral direction than that applied to a conventional structure without increasing the Ge composition of a buffer SiGe layer, and thus achieves a faster operation speed and lower power consumption, and a method of manufacturing the MOS field effect transistor.

It is another object of the present invention to provide an MOS field effect transistor, which is well matched with an existing process and is cost effective, without significantly changing the process steps by the MOS field effect transistor manufacture method.

In order to solve the above problems, the present invention has the following features.

1. A method of manufacturing an MOS field effect transistor according to the present invention comprises the steps of: forming a gate electrode on a top surface of a substrate comprising a compound layer having a lattice constant different from a lattice constant of silicon, and a silicon layer via an insulating film; forming a sidewall on a side wall of the gate electrode; exposing a side wall of the compound layer; and forming a silicon film on the side wall of the compound layer in a lattice matched manner.

2. An MOS field effect transistor according to the present invention comprises: a substrate comprising a compound layer having a lattice constant different from a lattice constant of silicon, and a silicon layer; a gate electrode formed on the substrate via an insulating film; a sidewall which covers a side wall of the gate electrode; and a silicon film formed on a side wall of the compound layer in a lattice matched manner.

### BRIEF DESCRIPTION OF THE DRAWINGS

FIG. 1 is a diagram showing the structure of an MOS field effect transistor according to the present invention;

FIG. 2 is a diagram for explaining the principle of the MOS field effect transistor according to the present invention;

FIG. 3 is a design diagram of the cross-sectional structure of the MOS field effect transistor according to the present invention;

FIGS. 4A and 4B are diagrams showing the structure of the MOS field effect transistor according to the present invention, in which FIG. 4A shows the regrowth junction interface of SiGe and Si being formed self-aligned with the side wall of the gate electrode, and FIG. 4B shows the SiGe/Si regrowth junction interface formed inward of the side wall of the gate electrode;

FIGS. 5C and 5D are diagrams showing the structure of the MOS field effect transistor according to the present invention, in which FIG. 5C shows the SiGe/Si regrowth junction interface being formed self-aligned with a region directly underlying the end portion of the outer wall of a sidewall on the gate electrode, and FIG. 5D shows the SiGe/Si regrowth junction interface formed between the side face of the gate electrode and a region directly underlying the end portion of the outer wall of the sidewall;

FIGS. 6E and 6F are diagrams showing the structure of the MOS field effect transistor according to the present invention, in which FIG. 6E shows the SiGe/Si regrowth junction interface extending outward of the gate electrode as the junction interface goes inward from the top surface of the substrate, and FIG. 6F shows the SiGe/Si regrowth junction interface extending inward of the gate electrode as the junction interface goes inward from the top surface of the substrate;

FIGS. 7A to 7C are diagrams showing a manufacture process for an MOS field effect transistor according to a first embodiment, in which FIG. 7A shows a state in which a gate insulating film and a gate electrode are formed in the Si/SiGe lamination, FIG. 7B shows a state in which source/drain regions are etched, and FIG. 7C shows a state in which Si is redoped by CVD;

FIGS. 8D to 8F are diagrams showing the manufacture process for the MOS field effect transistor according to the first embodiment, in which FIG. 8D shows a state in which a sidewall is formed after injection of an extension and an impurity is doped into the source/drain regions, FIG. 8E shows a state in which contact etching stop film is formed, and FIG. 8F shows a state in which an interlayer insulating film is formed, a contact hole is formed therein, and an electrode is formed;

FIGS. 9A to 9C are diagrams showing a manufacture process for an MOS field effect transistor according to a second embodiment, in which FIG. 9A shows a state in which gate insulating film and a gate electrode are formed in the Si/SiGe lamination, FIG. 9B shows a state in which source/drain regions are etched using a gate and a sidewall as a mask, and FIG. 9C shows a state in which Si is redoped by CVD;

FIGS. 10D to 10F are diagrams showing the manufacture process for the MOS field effect transistor according to the second embodiment, in which FIG. 10D shows a state in which a sidewall is formed after injection of an extension, FIG. 10E shows a state in which contact etching stop film is formed on a silicide, and FIG. 10F shows a state in which an interlayer insulating film is formed, a contact hole is formed therein, and an electrode is formed;

FIGS. 11A to 11C are diagrams showing a manufacture process for an MOS field effect transistor according to a third embodiment, in which FIG. 11A shows a state in which a gate insulating film and a gate electrode are formed in the Si/SiGe lamination, FIG. 11B shows a state in which source/drain regions are etched using the gate electrode and a sidewall as a mask, and FIG. 11C shows a state in which the etched region is redoped with Si;

FIGS. 12D to 12F are diagrams showing the manufacture process for the MOS field effect transistor according to the third embodiment, in which FIG. 12D shows a state in which source/drain regions are doped with an impurity, FIG. 12E shows a state in which contact etching stop film is formed on a silicide, and FIG. 12F shows a state in which an interlayer insulating film is formed, a contact hole is formed therein, and an electrode is formed;

FIGS. 13B, 13B′ and 13C are diagrams showing a manufacture process for an MOS field effect transistor according to a fourth embodiment, in which FIG. 13B shows a state in which source/drain regions are etched using a gate electrode and a sidewall as a mask, FIG. 13B′ shows a state in which a stressed Si layer and a buffer SiGe layer are selectively etched horizontally with respect to an insulating film and a sidewall, and FIG. 13C shows a state in which Si is regrown at the source/drain regions by CVD;

FIGS. 14B and 14C are diagrams showing a manufacture process for the MOS field effect transistor according to a fifth embodiment, in which FIG. 14B shows a state in which etching is performed in such a way that an Si/SiGe interface extends inward of a gate electrode as the interface goes inward from the top surface of a substrate, and FIG. 14C shows a state in which Si is regrown at the source/drain regions by CVD; and

FIGS. 15B, 15B′, and 15C are diagrams showing a manufacture process for an MOS field effect transistor according to a sixth embodiment, in which FIG. 15B shows a state in which source/drain regions are etched using a gate electrode 3 and a sidewall 16 as a mask, FIG. 15B′ shows a state in which a buffer SiGe layer is selectively etched with respect to a stressed Si layer, and FIG. 15C shows a state in which Si is regrown at the source/drain regions by CVD.

### DETAILED DESCRIPTION OF THE PREFERRED EMBODIMENTS

Exemplary embodiments of the present invention will be explained below with reference to the accompanying drawings. The following explanation is considered as illustrative only, and since variously changed and modified embodiments other than the one described can be made within the scope of the spirit of the appended claims by those skilled in the art, the embodiments do not limit the scope of the present invention.

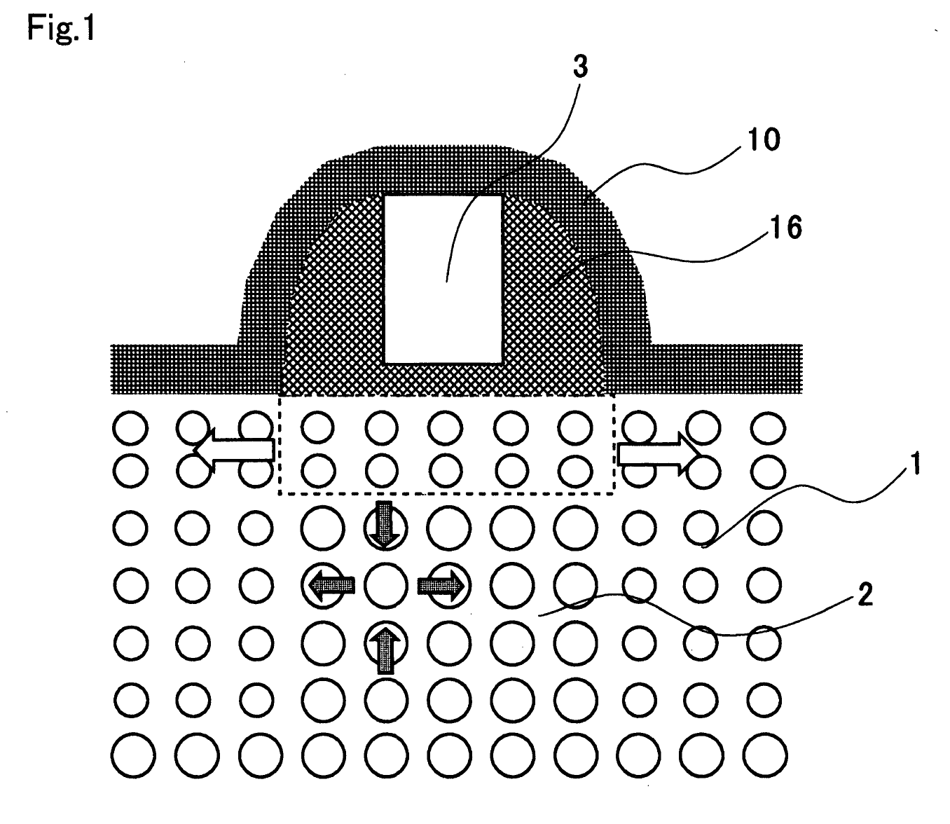

The principle of an MOS field effect transistor according to the embodiments of the present invention will be described with reference to FIGS. 1 to 3.

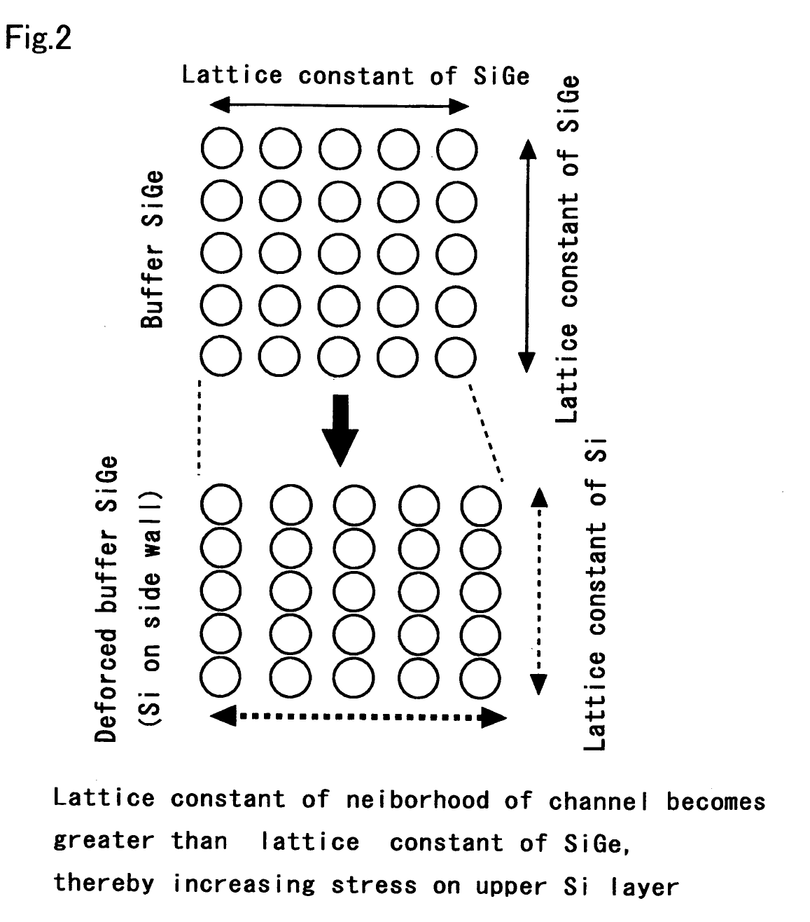

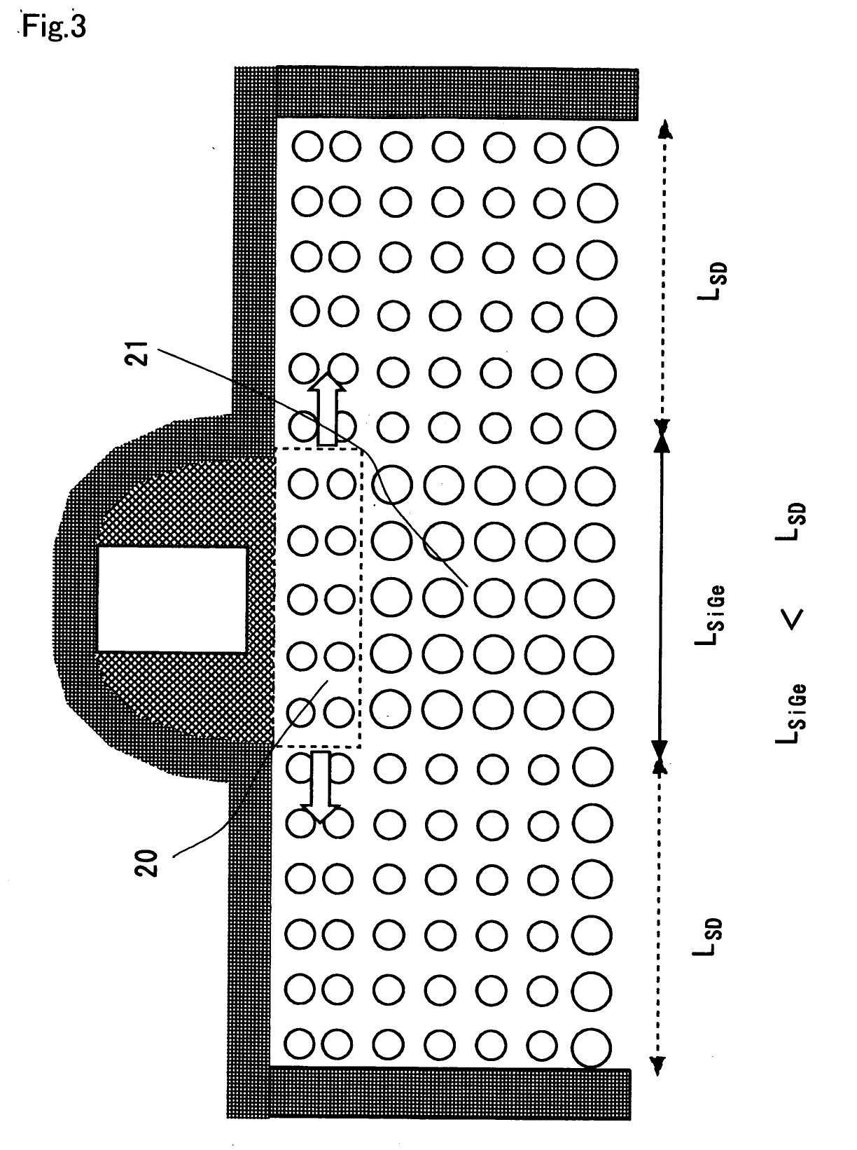

FIG. 1 is a diagram showing the structure of the MOS field effect transistor according to the present invention. FIG. 2 is a diagram for explaining the principle of the MOS field effect transistor according to the present invention. FIG. 3 is a design diagram of the cross-sectional structure of the MOS field effect transistor according to the present invention.

As shown in FIG. 1, an Si layer 1 and a buffer SiGe layer 2 of several micrometers, as two types of semiconductor layers with different lattice constants, are laminated, the former layer on the latter one, by a heterojunction, a side wall of the buffer SiGe layer 2 is exposed by an etching process, and Si is epitaxially doped and grown on that side wall, thereby reducing the vertical lattice constant of the buffer SiGe layer 2. This can increase the horizontal lattice constant of the buffer SiGe layer 2 without increasing the Ge composition of the buffer SiGe layer 2.

The percentage of the Ge composition is set to about 20% which is a practical level. If the percentage of the Ge composition is set to 30% or more, the dislocation density increases, thereby increasing the leak current, which results in an increase in power consumption of a semiconductor device. If the percentage of the Ge composition is set smaller, on the other hand, the dislocation density decreases, thus reducing the leak current, but the amount of stress on an Si channel layer becomes smaller, which reduces an improvement on mobility.

As shown in FIG. 2, doping the Si layer 1 at the side wall of the buffer SiGe layer 2 makes the lattice constant of the neighborhood of the Si channel greater than the lattice constant of the silicon layer of the buffer SiGe layer 2. This can increase the stress on the Si layer overlying the buffer SiGe layer 2.

As shown in FIG. 3, it is possible to easily make the vertical lattice constant of the buffer SiGe layer 2 smaller and the horizontal lattice constant thereof greater by setting a width, L_{SiGe}, of the buffer SiGe layer 2 smaller than a width, L_{SD}, of the doped Si layer 1 with respect to the channel direction.

The processes can apply larger tensile stress to a stressed Si channel in the lateral direction than that applied to the conventional structure without increasing the Ge composition of the buffer SiGe layer 2, thus achieving significant improvements on the electron mobility and the hole mobility of an nMOS and a pMOS.

The MOS field effect transistor according to the present invention takes the following six structures, depending on at which position in the channel direction Si is to be regrown on the side wall of the buffer SiGe layer.

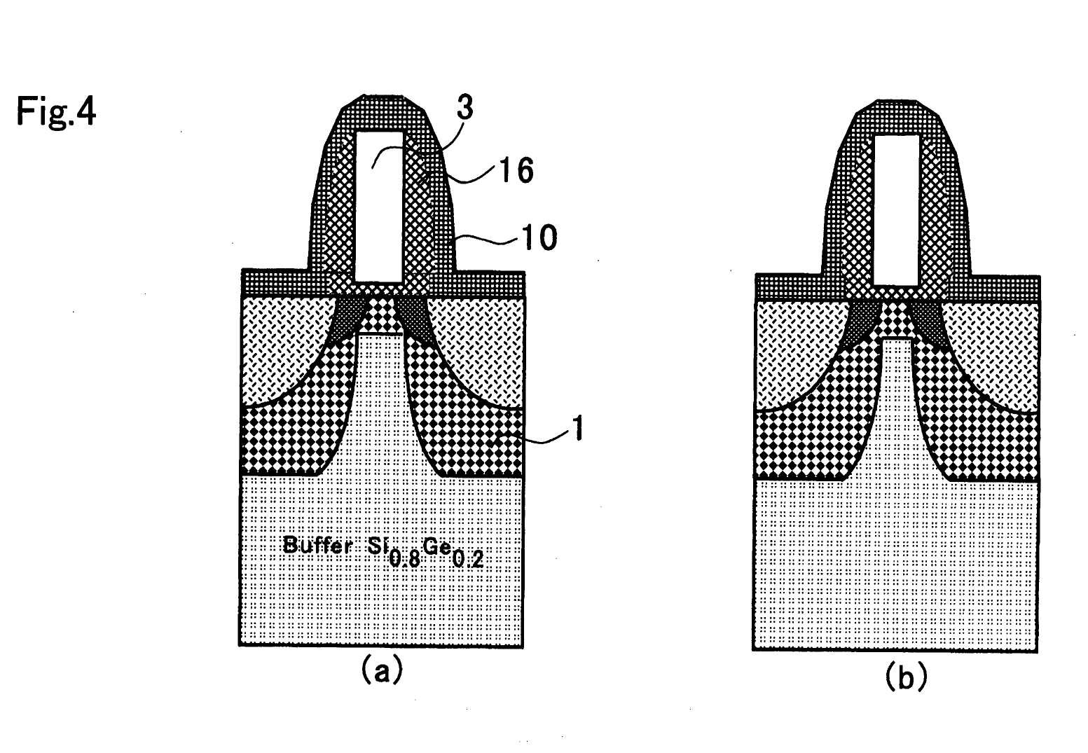

FIGS. 4A, 4B, 5C, 5D, 6E, and 6F are diagrams showing the structure of the MOS field effect transistor according to the present invention.

FIG. 4A shows a structure where the regrown junction interface of SiGe and Si is formed self-aligned with the side face of the gate electrode. As the regrowth junction interface where the Si layer 1 is regrown on the side wall of the SiGe layer 2 exposed by etching is formed on the side face of the gate electrode 3 in a self-aligned manner, large stress is applied only to the channel region under the gate electrode 3. As a parasitic resistor region is formed by Si, the parasitic resistor region can be formed by using an impurity doping technology which is used in manufacturing the conventional MOS type and CMOS type field effect transistors, such as ion injection.

FIG. 4B shows a structure where the SiGe/Si regrowth junction interface is formed inward of the side face of the gate electrode. As the interface is formed inward of the side face of the gate electrode 3, large stress is applied to the channel region, so that a pocket and extension pn junction can be constructed in such a way as not to cross the SiGe/Si heterojunction interface, thereby ensuring fabrication of an MOS field effect transistor with a high mobility and a low junction leak.

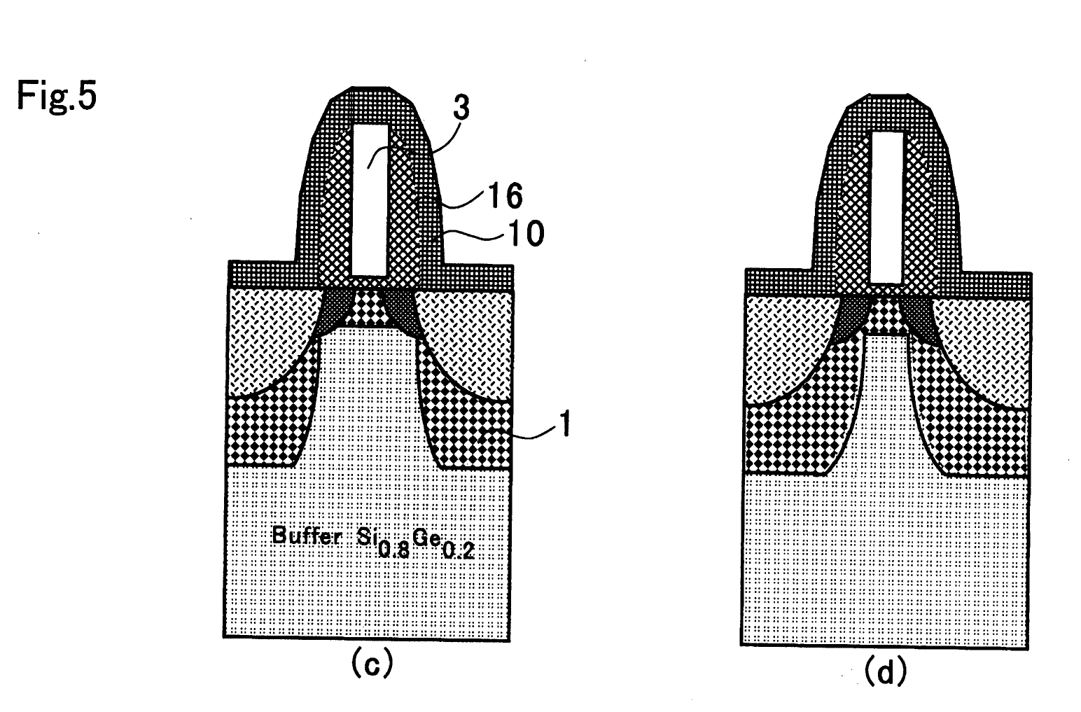

FIG. 5C shows a structure where the SiGe/Si regrowth junction interface is formed at a region directly underlying the end portion of the outer wall of a sidewall on the gate electrode in a self-aligned manner. As the interface is formed at the region directly underlying the end portion of the outer wall of the sidewall 16 on the gate electrode 3 in a self-aligned manner, large stress is applied to the channel region and the parasitic resistor region. This can ensure fabrication of a transistor with a high mobility and low parasitic resistance.

FIG. 5D shows a structure where the SiGe/Si regrowth junction interface is formed between a region directly underlying the side wall of the gate electrode and a region directly underlying the end portion of the outer wall of the sidewall. As the interface is formed between the region directly underlying the side wall of the gate electrode 3 and the region directly underlying the end portion of the outer wall of the sidewall 16, a pocket and extension pn junction can be constructed in such a way as not to cross the SiGe/Si heterojunction interface, thereby ensuring fabrication of an MOS field effect transistor with a high mobility, low parasitic resistance, and a small junction leak current.

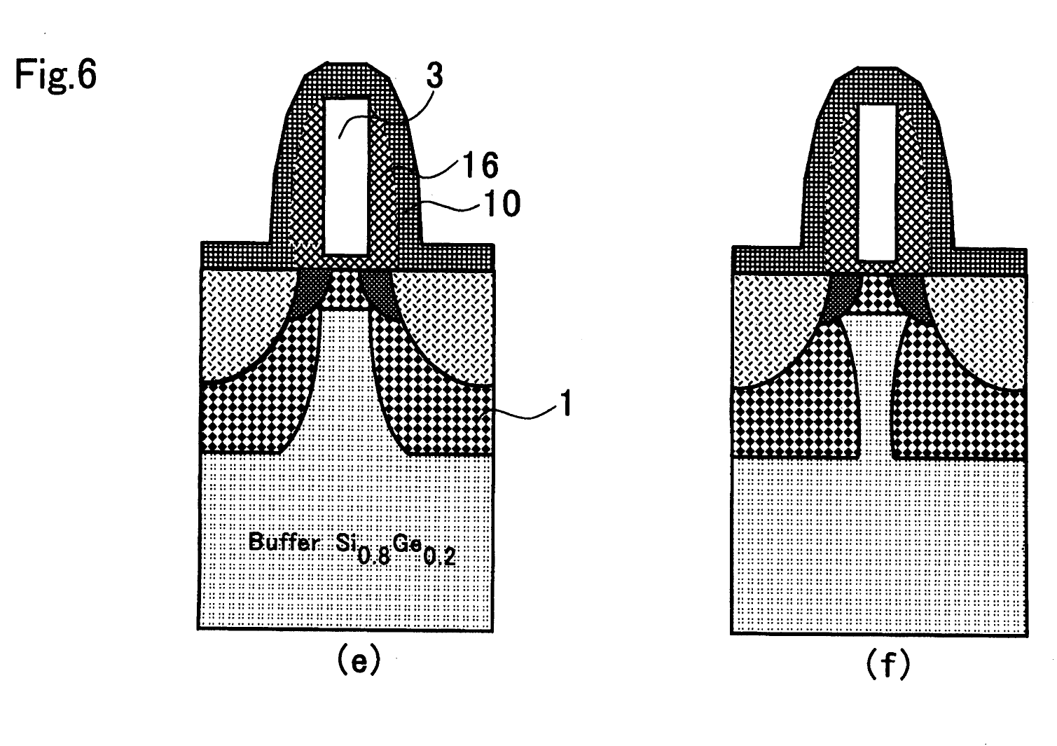

FIG. 6E shows a structure where the SiGe/Si regrowth junction interface extends outward of the gate electrode 3 as the junction interface goes inward from the top surface of the substrate. With this structure, a pocket and extension pn junction can be formed in such a way as not to cross the Si/SiGe heterojunction interface, thereby ensuring fabrication of an MOS field effect transistor with a small junction leak current.

FIG. 6F shows a structure where the SiGe/Si regrowth junction interface extends inward of the gate electrode 3 as the junction interface goes inward from the top surface of the substrate. With this structure, the horizontal stress on SiGe directly under the channel Si layer is maximized, and stress on the Si channel layer becomes large, so that particularly, an MOS field effect transistor with a high mobility can be fabricated.

### EMBODIMENTS

The present invention is further explained below with reference to embodiments, but the present invention is not limited to the embodiments.

### First Embodiment

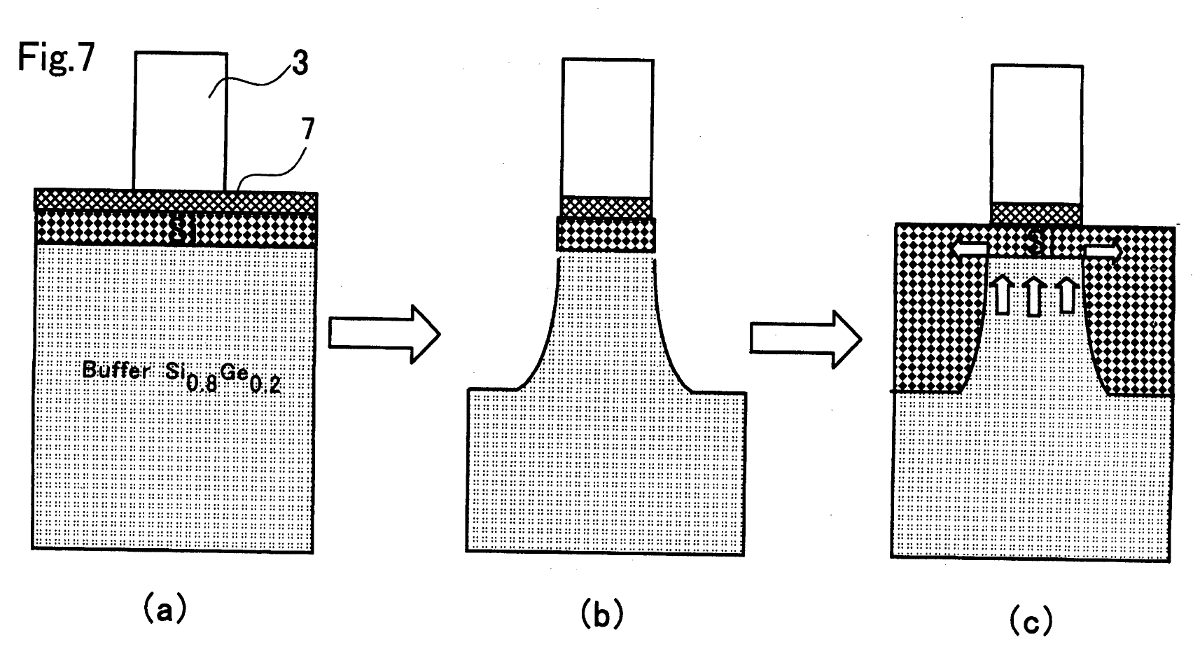

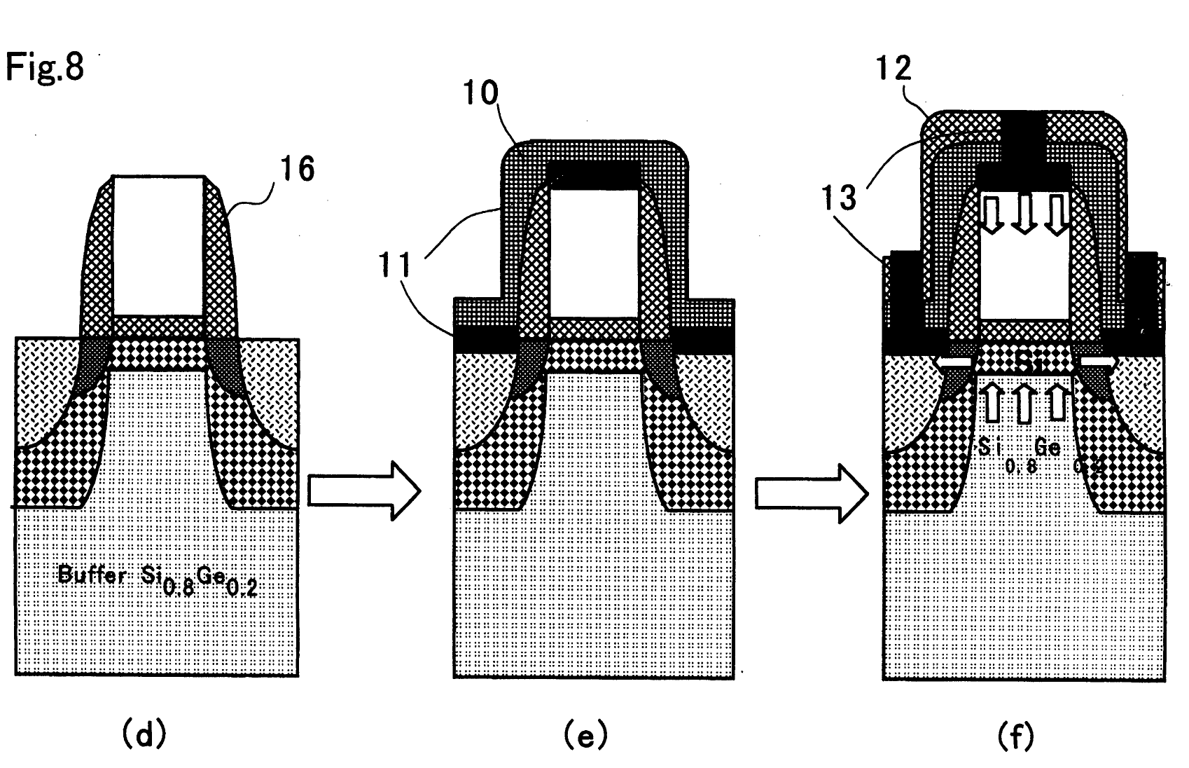

FIGS. 7A to 7C and FIGS. 8D to 8F are diagrams showing a manufacture process for an MOS field effect transistor according to a first embodiment. FIG. 7A shows a state in which a gate insulating film and a gate electrode are formed in the Si/SiGe lamination, FIG. 7B shows a state in which source/drain regions are etched, and FIG. 7C shows a state in which Si is redoped by CVD. FIG. 8D shows a state in which a sidewall is formed after injection of an extension and an impurity is doped into the source/drain regions, FIG. 8E shows a state in which contact etching stop film is formed, and FIG. 8F shows a state in which an interlayer insulating film is formed, a contact hole is formed therein, and an electrode is formed.

As shown in FIGS. 7A to 7C, after a device isolation step, a gate insulating film 7 of SiON and the gate electrode 3 of polysilicon are formed on a stressed silicon substrate having the buffer SiGe layer 2. Next, with the gate electrode 3 as a mask, the source/drain regions are etched, after which Si is redoped by CVD. The process can make the vertical lattice constant of the buffer SiGe layer 2 smaller, thereby increasing the horizontal lattice constant of the buffer SiGe layer 2 without increasing the Ge composition of the buffer SiGe layer 2. It is therefore possible to apply larger tensile stress to the stressed Si channel in the lateral direction than that applied to the conventional structure.

Next, as shown in FIGS. 8D to 8F, the sidewall 16 is formed after punch through stop and injection of an extension 17, and source/drain regions are doped with an impurity. For example, boron (B) is injected for a p-type, and arsenic (As), phosphorus (P), or the like is injected for an n-type. After injected ions are activated by activation annealing, NiSi, for example, is formed as a silicide 11. An SiN film having, for example, tensile stress is formed on the silicide 11 as a contact etching stop film 10, after which an interlayer insulating film 12 is formed, a contact hole is formed, and an electrode is formed.

The process can make large stress to be applied to the channel Si without increasing the Ge composition of the buffer SiGe layer 2, thereby ensuring fabrication of an MOS field effect transistor with a low leak current, a high mobility, and a high drive current.

### Second Embodiment

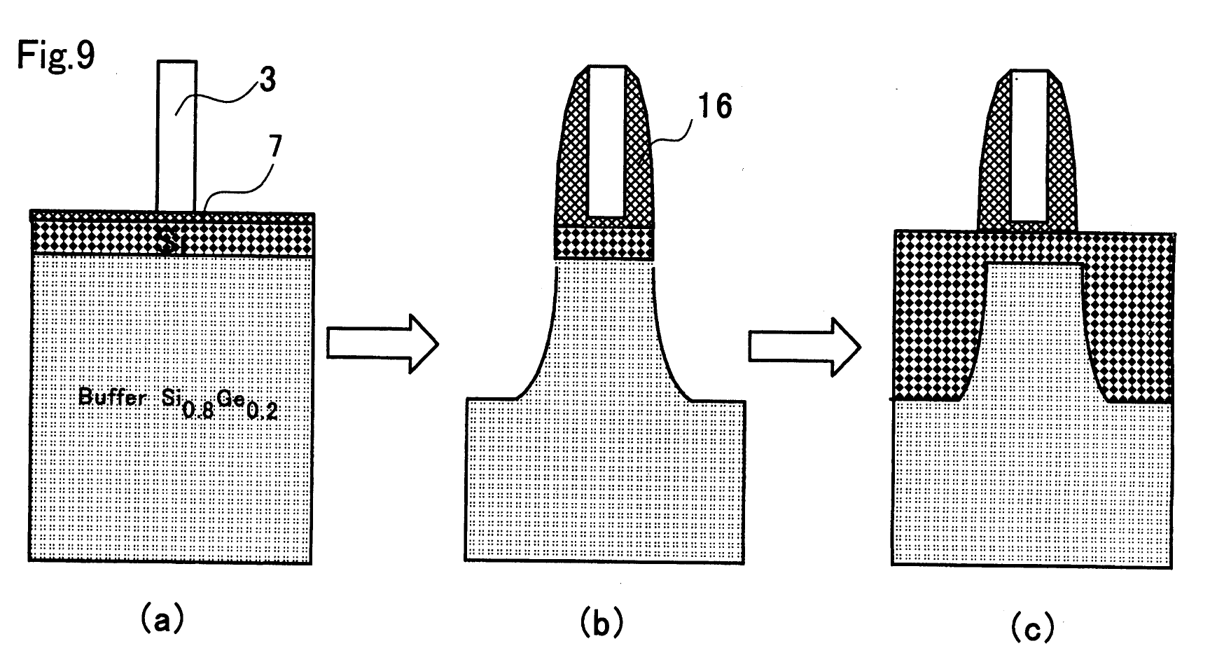

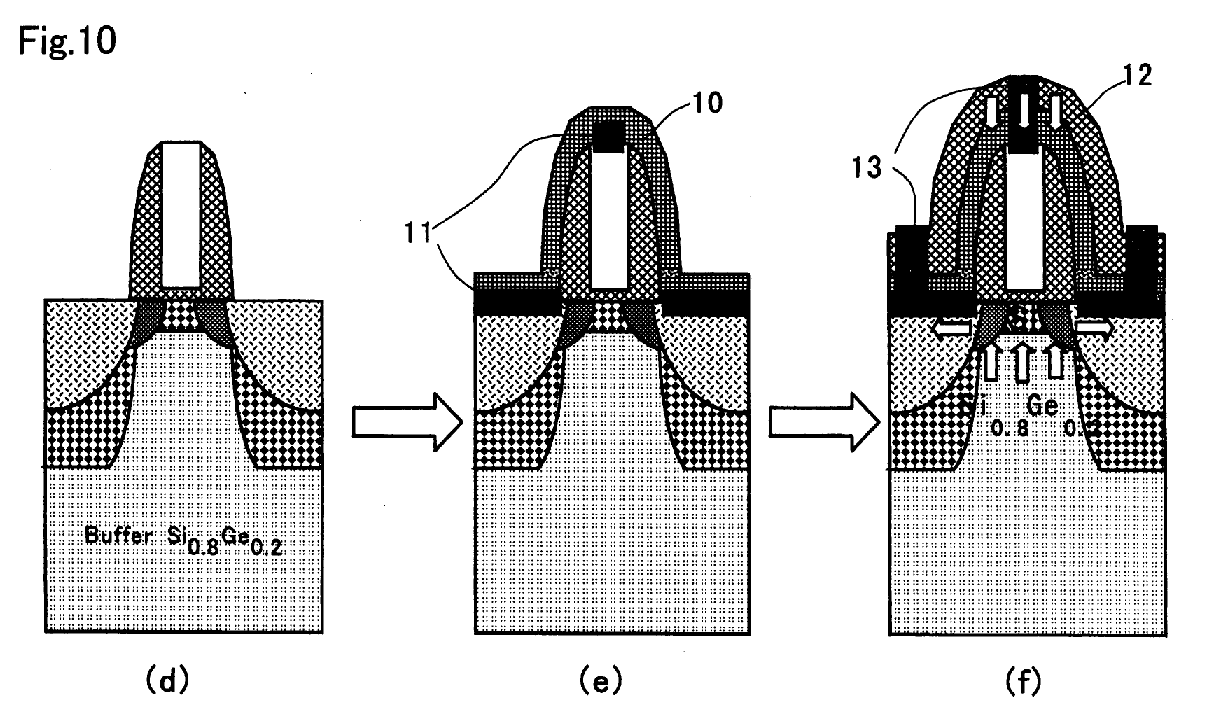

FIGS. 9A to 9C and FIGS. 10D to 10F are diagrams showing a manufacture process for an MOS field effect transistor according to a second embodiment. FIG. 9A shows a state in which gate insulating film and a gate electrode are formed in the Si/SiGe lamination, FIG. 9B shows a state in which source/drain regions are etched using a gate and a sidewall as a mask, and FIG. 9C shows a state in which Si is redoped by CVD. FIG. 10D shows a state in which a sidewall is formed after injection of an extension, FIG. 10E shows a state in which contact etching stop film is formed on a silicide, and FIG. 10F shows a state in which an interlayer insulating film is formed, a contact hole is formed therein, and an electrode is formed.

As shown in FIGS. 9A to 9C, after a device isolation step, the gate insulating film 7 of SiON and the gate electrode 3 of polysilicon are formed on a stressed silicon substrate having the buffer SiGe layer 2. Next, the sidewall 16 is formed on the gate electrode 3, and the source/drain regions are etched in a self-aligned manner using the sidewall 16 as a mask, after which Si is redoped by CVD.

The process can make the vertical lattice constant of the buffer SiGe layer 2 smaller, thereby increasing the horizontal lattice constant of the buffer SiGe layer 2 without increasing the Ge composition of the buffer SiGe layer 2. It is therefore possible to apply larger tensile stress to the stressed Si channel in the lateral direction than that applied to the conventional structure.

When the gate insulating film 7 is thin in the MOS field effect transistor prepared according to the first embodiment, the gate electrode 3 and the silicon layer of the source/drain regions which is redoped by CVD contact each other, thereby reducing the yield. The insertion of the sidewall 16 between the gate electrode 3 and the silicon layer as in the second embodiment brings about an advantage of significantly improving the yield.

Next, as shown in FIGS. 10D to 10F, the sidewall 16 is removed, the sidewall 16 is formed again after punch through stop and injection of an extension 17, and source/drain regions are doped with an impurity. After injected ions are activated by activation annealing, NiSi, for example, is formed as the silicide 11. An SiN film having, for example, tensile stress is formed on the silicide 11 as the contact etching stop film 10, after which the interlayer insulating film 12 is formed, a contact hole is formed, and the electrode 13 is formed.

The process can make large stress to be applied to the channel Si and the extension region 17 without increasing the Ge composition of the buffer SiGe layer 2, thereby ensuring fabrication of an MOS field effect transistor with a low leak current, a high mobility, a high drive current, and a low parasitic resistance.

### Third Embodiment

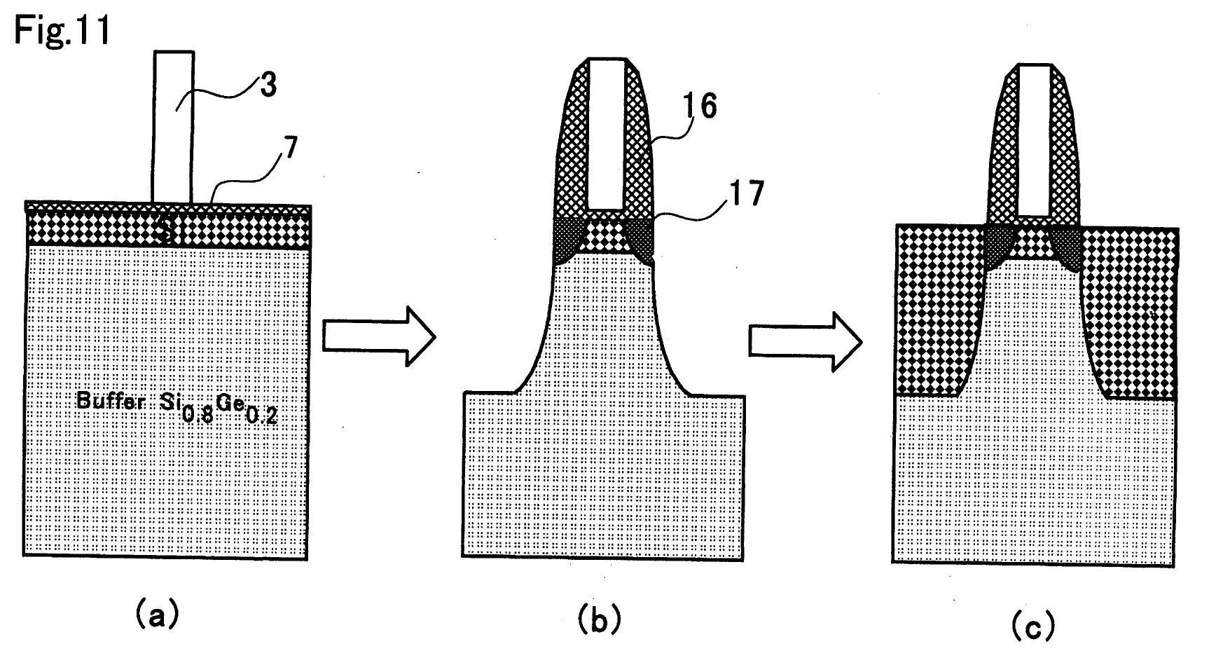

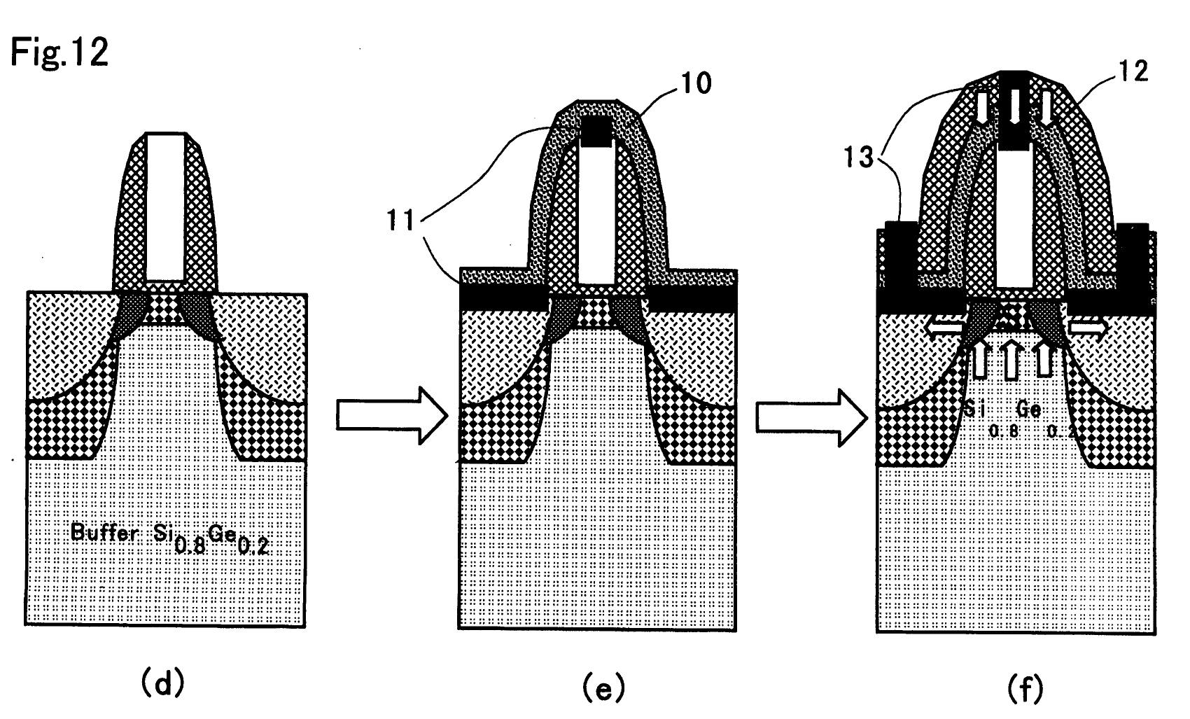

FIGS. 11A to 11C and FIGS. 12D to 12F are diagrams showing a manufacture process for an MOS field effect transistor according to a third embodiment. FIG. 11A shows a state in which a gate insulating film and a gate electrode are formed in the Si/SiGe lamination, FIG. 11B shows a state in which source/drain regions are etched using the gate electrode and a sidewall as a mask, and FIG. 11C shows a state in which the etched region is redoped with Si. FIG. 12D shows a state in which source/drain regions are doped with an impurity, FIG. 12E shows a state in which contact etching stop film is formed on a silicide, and Fig. 12F shows a state in which an interlayer insulating film is formed, a contact hole is formed therein, and an electrode is formed.

As shown in FIGS. 11A to 11C, after a device isolation step, the gate insulating film 7 of SiON and the gate electrode 3 of polysilicon are formed on a stressed silicon substrate having the buffer. SiGe layer 2. Next, the sidewall 16 is formed after punch through stop and injection of an extension, and the source/drain regions are etched in a self-aligned manner using the sidewall 16 as a mask, after which Si is redoped by CVD.

The process can make the vertical lattice constant of the buffer SiGe layer 2 smaller, thereby increasing the horizontal lattice constant of the buffer SiGe layer 2 without increasing the Ge composition of the buffer SiGe layer 2. It is therefore possible to apply larger tensile stress to the stressed Si channel in the lateral direction than that applied to the conventional structure.

When the gate insulating film 7 is thin in the MOS field effect transistor prepared according to the. first embodiment, the gate electrode 3 and the silicon layer 1 of the source/drain regions which is redoped by CVD contact each other, thereby reducing the yield. The insertion of the sidewall 16 between the gate electrode 3 and the silicon layer 1 as in the third embodiment brings about an advantage of significantly improving the yield.

Next, as shown in FIGS. 12D to 12F, source/drain regions are doped with an impurity. After injected ions are activated by activation annealing, NiSi, for example, is formed as the silicide 11. An SiN film having, for example, tensile stress is formed on the silicide 11 as the contact etching stop film 10, after which the interlayer insulating film 12 is formed, a contact hole is formed, and the electrode 13 is formed.

The process can make large stress to be applied to the channel Si and the extension region 17 without increasing the Ge composition of the buffer SiGe layer 2, thereby ensuring fabrication of an MOS field effect transistor with a low leak current, a high mobility, a high drive current, and a low parasitic resistance.

### Fourth Embodiment

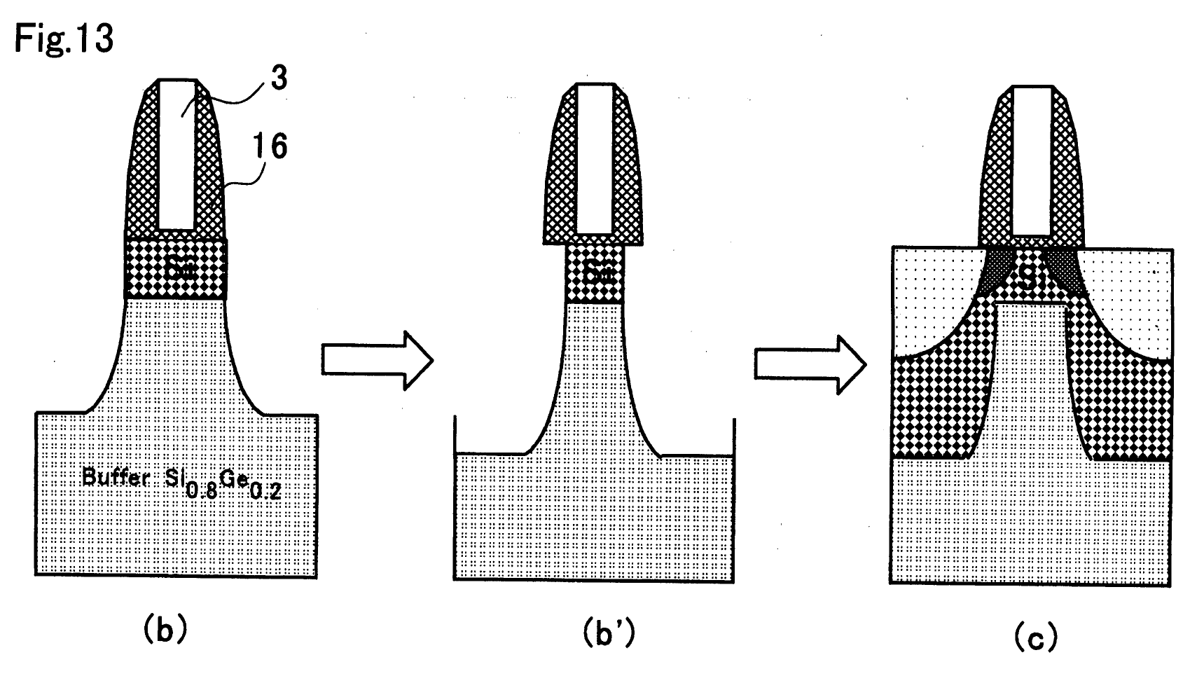

FIGS. 13A, 13B′, and 13C are diagrams showing a manufacture process for an MOS field effect transistor according to a fourth embodiment. FIG. 13B shows a state in which source/drain regions are etched using a gate electrode and a sidewall as a mask, FIG. 13B′ shows a state in which a stressed Si layer and a buffer SiGe layer are selectively etched horizontally with respect to an insulating film and a sidewall, and FIG. 13C shows a state in which Si is regrown at the source/drain regions by CVD.

The fourth embodiment is an example in which the first to the third embodiments are further developed. First, to reduce the junction leak current between the source/drain regions and the body, the source/drain regions are etched with the sidewall 16 formed on the gate electrode 3. then, a stressed Si/buffer SiGe layer is selectively etched horizontally with respect to the insulating film and the sidewall 16 in such a way that a pocket and extension pn junction does not cross the heterojunction interface between Si and SiGe and the junction leak current is reduced, thereby regrowing Si at the source/drain regions by CVD.

The process can reduce the junction leak current between the source/drain regions and the body, thereby improving the yield.

### Fifth Embodiment

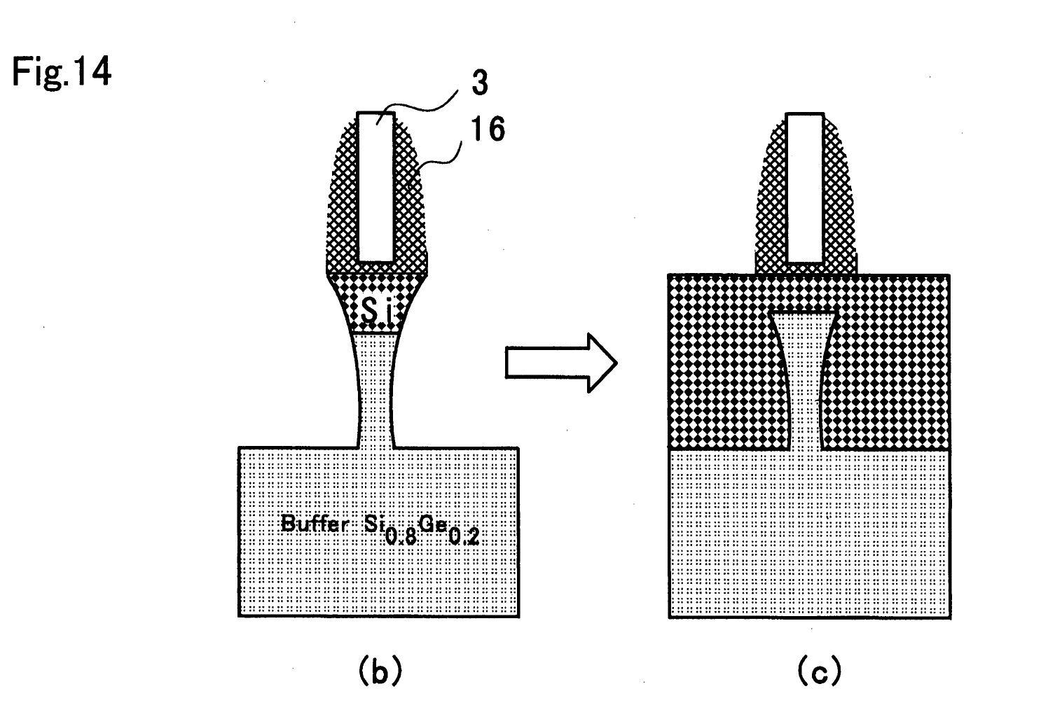

FIGS. 14B and 14C are diagrams showing a manufacture process for an MOS field effect transistor according to a fifth embodiment. 14B shows a state in which etching is performed in such a way that an Si/SiGe interface extends inward of a gate electrode as the interface goes inward from the top surface of a substrate, and FIG. 14C shows a state in which Si is regrown at the source/drain regions by CVD.

The fifth embodiment is an example in which the first to the third embodiments are further developed. First, to reduce the junction leak current between the source/drain regions and the body, the source/drain regions are etched with the sidewall 16 formed on the gate electrode 3. At this time, the Si/SiGe interface is formed in such a way as to extend inward from the top surface of the substrate. This increases the horizontal stress at the stressed Si/buffer SiGe interface. Then, Si is regrown at the source/drain regions by CVD, thereby ensuring fabrication of an MOS field effect transistor with a high mobility.

### Sixth Embodiment

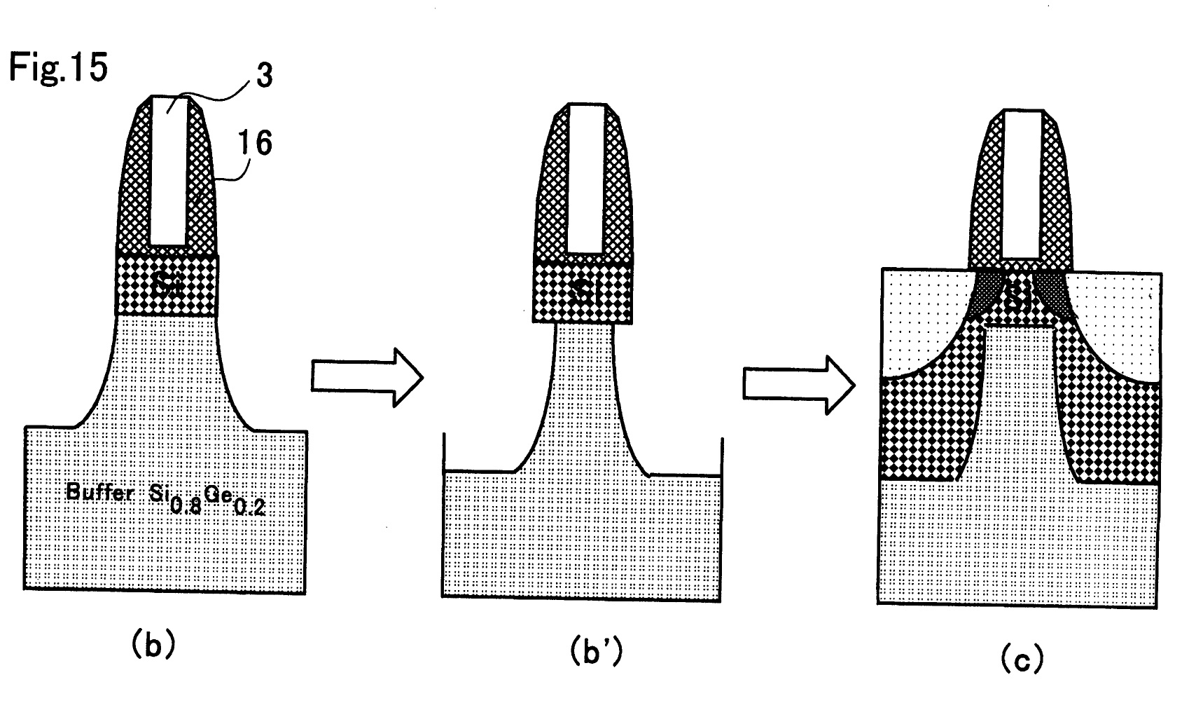

FIGS. 15B, 15B′, and 15C are diagrams showing a manufacture process for an MOS field effect transistor according to a sixth embodiment. FIG. 15B shows a state in which source/drain regions are etched using the gate electrode and the sidewall as a mask, FIG. 15B′ shows a state in which a buffer SiGe layer is selectively etched with respect to a stressed Si layer, and FIG. 15C shows a state in which Si is regrown at the source/drain regions by CVD.

The sixth embodiment is an example in which the first to the third embodiments are further developed. First, to reduce the junction leak current between the source/drain regions and the body, the source/drain regions are etched with the sidewall 16 formed on the gate electrode 3. Then, the buffer SiGe layer 2 is selectively etched with respect to the stressed Si layer 1 in such a way as to provide the aspect ratio at which the horizontal stress at the stressed Si/buffer SiGe interface becomes maximum. Then, Si is regrown at the source/drain regions by CVD, thereby tuning the device structure to further enhance the mobility.

The present invention can provide a method of manufacturing an MOS field effect transistor, which improves the mobility of electrons and holes of an nMOS and a pMOS by applying larger tensile stress to a stressed Si channel in a lateral direction than that applied to a conventional structure without increasing the Ge composition of the buffer SiGe layer, and thus achieves a faster operation speed and lower power consumption.

The use of the manufacture method can provide an MOS field effect transistor, which is well matched with an existing process and is cost effective, without significantly changing the process steps.

1. A method of manufacturing an MOS field effect transistor, comprising the steps of:
forming a gate electrode on a top surface of a substrate comprising a compound layer having a lattice constant different from a lattice constant of silicon, and a silicon layer via an insulating film;
forming a sidewall on a side wall of the gate electrode;
exposing a side wall of the compound layer; and
forming a silicon film on the side wall of the compound layer in a lattice matched manner.

2. The method of manufacturing an MOS field effect transistor according to claim 1, wherein the compound layer comprises a buffer silicon germanium layer.

3. The method of manufacturing an MOS field effect transistor according to claim 2, wherein a width of the silicon film is greater than a width of the buffer silicon germanium layer with respect to a gate length direction.

4. The method of manufacturing an MOS field effect transistor according to claim 2 or 3, wherein the silicon film is formed on the side wall of the buffer silicon germanium layer in such a way as to be self-aligned with the gate electrode.

5. The method of manufacturing an MOS field effect transistor according to claim 2, wherein a junction interface between the buffer silicon germanium layer and the silicon film is formed inward of the side wall of the gate electrode with respect to the gate length direction.

6. The method of manufacturing an MOS field effect transistor according to claim 2, wherein a junction interface between the buffer silicon germanium layer and the silicon film is formed in such a way as to be self-aligned with the sidewall of the gate electrode.

7. The method of manufacturing an MOS field effect transistor according to claim 2, wherein a junction interface between the buffer silicon germanium layer and the silicon film is present between a region directly underlying the side wall of the gate electrode and a region directly underlying an end portion of an outer wall of the sidewall.

8. The method of manufacturing an MOS field effect transistor according to claim 2, wherein a junction interface between the buffer silicon germanium layer and the silicon film extends outward of the gate electrode as the junction interface goes inward from the top surface of the substrate.

9. The method of manufacturing an MOS field effect transistor according to claim 2, wherein a junction interface between the buffer silicon germanium layer and the silicon film extends inward of the gate electrode as the junction interface goes inward from the top surface of the substrate.

10. The method of manufacturing an MOS field effect transistor according to claim 2, wherein the width of the buffer silicon germanium layer with respect to the gate length direction is controlled by selectively etching the buffer silicon germanium layer with respect to the silicon film.

11. An MOS field effect transistor comprising;
a substrate comprising a compound layer having a lattice constant different from a lattice constant of silicon, and a silicon layer;
a gate electrode formed on the substrate via an insulating film;
a sidewall which covers a side wall of the gate electrode; and
a silicon film formed on a side wall of the compound layer in a lattice matched manner.

12. The MOS field effect transistor according to claim 11, wherein the compound layer comprises a buffer silicon germanium layer.

13. The MOS field effect transistor according to claim 12, wherein a width of the silicon film is greater than a width of the buffer silicon germanium layer with respect to a channel direction.

14. The MOS field effect transistor according to claim 12, wherein the silicon film comprises a parasitic resistor region.

15. The MOS field effect transistor according to claim 12, wherein a junction interface between the buffer silicon germanium layer and the silicon film is present inward of a region directly underlying the side wall of the gate electrode with respect to the gate length direction.

16. The MOS field effect transistor according to claim 12, wherein a junction interface between the buffer silicon germanium layer and the silicon film lies along an outer wall end of the sidewall.

17. The MOS field effect transistor according to claim 12, wherein a junction interface between the buffer silicon germanium layer and the silicon film is present between a region directly underlying the side wall of the gate electrode and a region directly underlying an end portion of an outer wall of the sidewall.

18. The MOS field effect transistor according to any one of claim 12, wherein a junction interface between the buffer silicon germanium layer and the silicon film extends outward of the gate electrode as the junction interface goes inward from the top surface of the substrate.

19. The MOS field effect transistor according to any one of claim 12, wherein a junction interface between the buffer silicon germanium layer and the silicon film extends inward of the gate electrode as the junction interface goes inward from the top surface of the substrate.
